(19) United States
(12) Patent Application Publication
(10) Pub. No.: US 2014/0339606 A1
(43) Pub. Date: Nov. 20, 2014

(54) BSI CMOS IMAGE SENSOR

(71) Applicant: VisEra Technologies Company Limited, Hsin-Chu City (TW)

(72) Inventors: Chi-Han LIN, Zhubei City (TW); Zong-Ru TU, Keelung City (TW); Yu-Kun HSIAO, Hsin-Chu City (TW); Chih-Kung CHANG, Chu-Tung (TW)

(73) Assignee: VisEra Technologies Company Limited, Hsin-Chu City (TW)

(21) Appl. No.: 14/096,440

(22) Filed: Dec. 4, 2013

Related U.S. Application Data
(63) Continuation-in-part of application No. 13/895,819, filed on May 16, 2013.

(51) Int. Cl. H01L 27/146

(52) U.S. Cl. CPC H01L 27/1463; H01L 27/14685
USPC 257/228; 438/70

(57) ABSTRACT

A back surface illuminated image sensor is provided. The back surface illuminated image sensor includes: a first passivation layer disposed on the photodiode array; an oxide grid disposed on the first passivation layer and forming a plurality of holes exposing the first passivation layer; a color filter array including a plurality of color filters filled into the holes, wherein the oxide grid has a refractive index smaller than that of plurality of color filters; and a metal grid aligned to the oxide grid, wherein the metal grid has an extinction coefficient greater than zero.

### CROSS REFERENCE

This application is a Continuation-In-Part of application Ser. No. 13/895,819, filed on May 16, 2013, the entirety of which is incorporated by reference herein.

### TECHNICAL FIELD

The present disclosure relates generally to an optoelectronic device, and more particularly to a back surface illuminated (BSI) complementary metal oxide semiconductor (CMOS) image sensor.

### BACKGROUND

CMOS image sensors are gaining in popularity over traditional charge-coupled devices (CCDs) due to certain advantages inherent in the CMOS image sensors. In particular, CMOS image sensors typically require lower voltages, consume less power, enable random access to image data, and may be fabricated with compatible CMOS processes.

CMOS image sensors utilize a photodiode array to convert light energy into electrical energy and can be designed to be illuminated from a front surface or from a back surface. The back surface illuminated (BSI) CMOS image sensors can optimize the optical path independent of the electrical wiring arrange and disturbance, such that the BSI CMOS image sensors can ultimately achieve higher quantum efficiency than the front surface illuminated CMOS image sensors that receive the incident light on the front side of semiconductor substrate which the electrical wiring layer is formed.

With the trend of size reduction of pixels of the BSI CMOS image sensors, each pixel receive lower amount of incident light and suffers more cross-talk with adjacent pixels. It is a demand to improve sensitivity and prevent cross-talk for further miniaturization requirements.

### SUMMARY

Accordingly, a back surface illuminated CMOS image sensor is provided. The back surface illuminated CMOS image sensor includes a first passivation layer disposed on a photodiode array; an oxide grid disposed on the first passivation layer and forming a plurality of holes exposing the first passivation layer; a color filter array including a plurality of color filters filled into the holes, wherein the oxide grid has a refractive index smaller than that of the plurality of color filters; and a metal grid aligned to the oxide grid, wherein the metal grid has an extinction coefficient greater than zero.

Accordingly, a back surface illuminated CMOS image sensor is provided. The back surface illuminated CMOS image sensor includes a plurality of unit pixels, each unit pixel includes a photodiode and at least one pixel transistor; a plurality of color filters on the unit pixels; a first passivation layer between the photodiodes and the color filters; an oxide grid including a trapezoid shape interposed between the color filters of the pixels; and a metal grid comprising a trapezoid shape aligned to the oxide grid, wherein the oxide grid has a refractive index smaller than that of the plurality of color filters, and wherein the metal grid has an extinction coefficient greater than zero.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1A shows a cross-sectional view of a BSI CMOS image sensor according to an embodiment of the present disclosure.

FIG. 1B shows a top view of the BSI CMOS image sensor shown in FIG. 1A.

FIGS. 2-6 show cross-sectional views of a BSI CMOS image sensor according to various embodiments of the present disclosure.

FIG. 7A shows a cross-sectional view of a BSI CMOS image sensor according to an embodiment of the present disclosure.

FIGS. 7B and 7C show top views of a BSI CMOS image sensor according to some embodiments of the present disclosure.

FIGS. 8-10 show cross-sectional views of BSI CMOS image sensors according to some embodiments of the present disclosure.

FIGS. 11A-11G show cross-sectional views at intermediate stages of forming a BSI CMOS image sensor according to some embodiments of the present disclosure.

FIGS. 12A-12B show cross-sectional views at intermediate stages of forming a BSI CMOS image sensor according to some embodiments of the present disclosure.

FIGS. 13A-13B show cross-sectional views at intermediate stages of forming a BSI CMOS image sensor according to some embodiments of the present disclosure.

FIGS. 14A-14B show cross-sectional views at intermediate stages of forming a BSI CMOS image sensor according to some embodiments of the present disclosure.

### DETAILED DESCRIPTION

The following description is of the best-contemplated mode of carrying out the invention. This description is made for the purpose of illustrating the general principles of the invention and should not be taken in a limiting sense. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. The scope of the invention is best determined by reference to the appended claims.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

A method for resolving the cross-talk issue is forming a metal grid disposed under color filters. The metal grid would absorb (or block) the incident light such that the incident light would not diffuse to the neighboring pixels. The cross-talk issue can be substantially reduced by the formation of the metal grid, but the quantum efficiency of the BSI CMOS image sensors is affected since a portion of the incident light absorbed by the metal grid cannot reach the photodiode array.

Embodiments according to the present disclosure disclose embodiments of a BSI CMOS image sensor which comprises a metal grid with an oxide grid for further enhancing the quantum efficiency while resolving the cross-talk, providing a high chief ray angle tolerance and improving sensitivity.

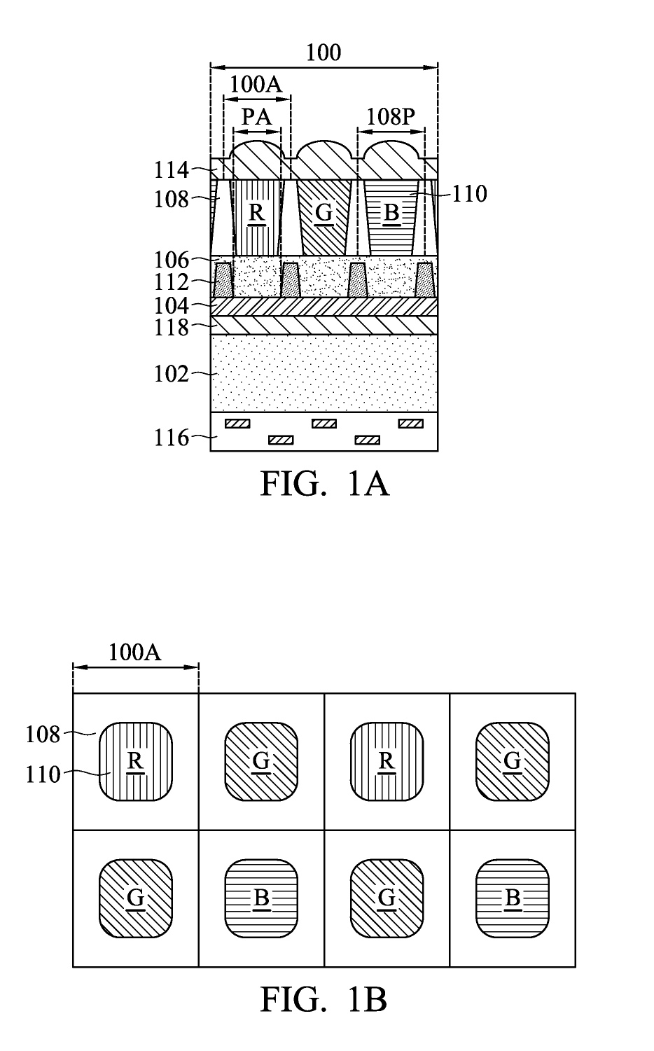

FIG. 1A shows a cross-sectional view of the BSI CMOS image sensor according to an embodiment of the present disclosure. In an embodiment, the BSI CMOS image sensor may comprise a pixel region 100 in which a plurality of unit pixels 100A is arranged in a semiconductor substrate made of silicon, and a peripheral circuit section (not shown) disposed in a periphery of the pixel region 100. A photodiode array 102 comprising a plurality of photodiodes and a plurality of pixel transistors (not shown) may be formed through of the overall region semiconductor substrate in the pixel region 100.

A first passivation layer 104 and a second passivation layer 106 may be disposed on the photodiode array 102. In an embodiment, the second passivation layer 106 may be disposed on the first passivation layer 104. The first passivation layer 104 and the second passivation layer 106 may be formed of the same or different materials. For example, the first and second passivation layers 104 and 106 may be formed of silicon oxide, silicon nitride, Ta₂O₅, HfO₂, or a combination thereof. The first and second passivation layers 104 and 106 may function as an etch stop layer during the fabrication of the peripheral circuit (not shown). In some embodiments, the first passivation layer 104 can be omitted if it is permitted by the fabricating process. Alternatively, another passivation layer 118 or more passivation layers may be formed between the passivation layers 104 and 106 and the photodiode array 102.

An oxide grid 108 may be disposed on the second passivation layer 106. The oxide grid 108 may be arranged periodically around the unit pixels 100A and form a plurality of holes exposing the second passivation layer 106. A color filter array 110 comprising a plurality of color filters 110 is filled into the holes. In an embodiment, the oxide grid 108 may have tapered sidewalls, and therefore the color filters 110 may have reverse-tapered sidewalls. As shown in FIG. 1A, the oxide grid 108 and the color filters 110 may have a trapezoid shape and a reversed trapezoid shape, respectively. For example, the oxide grid 108 may have a bottom surface wider than or equal to its top surface, and the color filters 110 may have a bottom surface narrower than their top surface.

In an embodiment, the top surfaces of the oxide grid 108 and the color filters 110 may be substantially level with each other. The oxide grid 108 may have a periodic interval 108P substantially equal to the width of the unit pixels 100A. The color filters 110 may at least comprise three primary colors, such as red, green and blue (R, G and B), and each of them may be arranged in any suitable combination. For example, referring to FIG. 1B, it shows a top view of the BSI CMOS image sensor shown in FIG. 1A while removing the microlens structure 114. Each photodiode 102 in the unit pixels 100A corresponds to one of the three primary colors, and the colors are alternately arranged. The oxide grid 108 may surround the color filters 110 for blocking the incident light diffusing to neighboring unit pixels 100A. As shown in FIG. 1B, the holes filled with the color filters 110 may be a square with rounded corners. Alternatively, the holes may have a circular shape.

In other words, the oxide gird 108 is a three-dimensional structure. The oxide grid 108 is made up of a series of intersecting perpendicular and horizontal axes for separating the adjacent color filters 110. In the cross-section view, the oxide grid 108 may be formed as a plurality of periodic parallel partitions, and the distance between two parallel partitions is substantially equal to the dimension of a unit pixel 100A.

A metal grid 112 may be embedded in the second passivation layer 106. For example, the metal grid 112 may stand on the first passivation layer 104 and align with the oxide grid 108. In addition, the metal grid 112 may be spaced apart from the oxide grid 108 and the color filters 110 by the second passivation layer 106 such that the oxide grid 108 may be protected by the second passivation layer 116. The metal grid 112 may be arranged periodically around the unit pixels 100A to prevent static electricity damage. The metal grid 112 may be tapered sidewalls (i.e.; having a trapezoid shape in the cross-section view). For example, the metal grid 112 may have a bottom surface wider than its upper surface, and the sidewalls of the metal grid may be inclined and have an angle of between about 50° and about 90° with the bottom of the metal grid. The metal grid 112 may have a height of between about 0.05 μm and about 1.0 μm. The metal grid 112 may have a bottom width of about 5.7% to about 30% of the periodic interval 108P of the oxide grid 108 (or the width of the unit pixels 100A). In an embodiment, the metal grid 112 may be formed of W, Cu, AlCu or a combination thereof.

In other words, the metal gird 112 is a three-dimensional structure. The metal grid 112 is made up of a series of intersecting perpendicular and horizontal axes and is aligned to the oxide grid 108. In the cross-section view, the metal grid 108 may be formed as a plurality of periodic parallel partitions.

The oxide grid 108 may have a refractive index greater than that of all of the color filters 110. The refractive index is a property of a material that changes the speed of light and is computed as the ratio of the speed of light in a vacuum to the speed of light through the material. When light travels at an angle between two different materials, their refractive indices determine the angle of transmission (refraction) of the light beam. In general, the refractive index varies based on the frequency of the light as well, thus different colors of light travel at different speeds. High intensities also can change the refractive index. In this embodiment, the color filters 110 of the RGB (or cyan, magenta, yellow or clear) may have different refractive indices, and the oxide grid 108 may have the refractive index smaller than that of either one of the color filters.

The metal grid 112 may have an extinction coefficient greater than zero for blocking the incident light diffusion. For example, the metal grid 112 may mainly block the incident light by absorbing it, and the oxide grid 108 may mainly block the incident light by reflecting it. The oxide grid 108 may reflect the incident light diffusion such that a portion of the incident light that may diffuse to neighboring pixels can be reflected back to the targeted unit pixels 100A. In addition, a portion of the incident light that may be absorbed by the metal grid 112 may be reflected by the oxide grid 108 before the incident light reaches the metal grid 112. Thus, by forming the oxide grid 108, the size of the metal grid 112 may be reduced without deteriorating the cross-talk, and a lower portion of the incident light may be absorbed by the metal grid 112. The BSI CMOS image sensor according to the present embodiment may have enhanced quantum efficiency with low cross-talk.

In addition, when compared to the conventional BSI CMOS image sensor (containing the metal grid only), the light-receiving area PA of the unit pixels 100A may not be reduced if the oxide grid 108 is not wider than the metal grid 112. In an embodiment, the oxide grid 108 may have a bottom width substantially equal to that of the metal grid 112. In addition, the light-receiving area PA of the unit pixels 100A may be enlarged since the size of metal grid 112 may be reduced.

A microlens structure 114 may be disposed on the color filter array 110 and the oxide grid 108 for focusing an incident light toward the photodiode array and reducing the incident light diffusion. An interconnection layer 116 may be formed on the back surface of the semiconductor substrate, independent of the optical path.

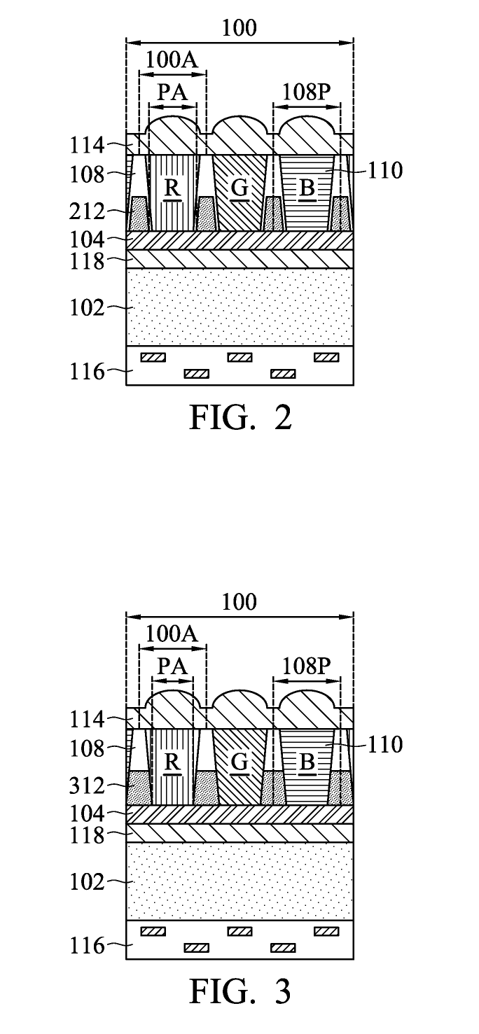

FIG. 2 shows a cross-sectional view of a BSI CMOS image sensor according to another embodiment of the present disclosure. In this embodiment, the BSI CMOS image sensor is similar to the BSI CMOS image shown in FIG. 1A except that the metal grid is embedded in the oxide gird. Like reference numerals in this embodiment are used to indicate elements substantially similar to the elements described in the above embodiments, and a detailed description of the substantially similar elements will not be repeated.

Referring to FIG. 2, the BSI CMOS image sensor may comprise a pixel region 100 in which a plurality of unit pixels 100A is arranged in a semiconductor substrate made of silicon, and a peripheral circuit section (not shown) disposed in a periphery of the pixel region 100. A photodiode array 102 comprising a plurality of photodiodes and a plurality of pixel transistors (not shown) may be formed through the overall region of the semiconductor substrate in the pixel region 100.

A first passivation layer 104 may be disposed on the photodiode array 102. The first passivation layer 104 may be formed of silicon oxide, silicon nitride, Ta₂O₅, HfO₂, or a combination thereof. The first passivation layer 104 may function as an etch stop layer during the fabrication of the peripheral circuit (not shown). In some embodiments, the first passivation layer 104 can be omitted if it is permitted by the fabricating process. Alternatively, another passivation layer 118 or more passivation layers may be formed between the first passivation layer 104 and the photodiode array 102.

An oxide grid 108 may be disposed on the passivation layer 104. The oxide grid 108 may be periodically arranged around the unit pixels 100A and form a plurality of holes exposing the first passivation layer 104. A color filter array 110 comprising a plurality of color filters 110 is filled into the holes. In an embodiment, the oxide grid 108 may have tapered sidewalls, and therefore the color filters 110 may have reverse-tapered sidewalls. For example, the oxide grid 108 may have a bottom surface wider than or equal to its top surface, and the color filters 110 may have a bottom surface narrower than its top surface. In an embodiment, the top surfaces of the oxide grid 108 and the color filters 110 may be substantially level with each other. The oxide grid 108 may have a periodic interval 108P substantially equal to the width of the unit pixels 100A. The color filters 110 may at least comprise three primary colors, such as red, green, and blue (R, G and B), with each arranged in any suitable combination.

A metal grid 212 may be embedded in the oxide grid 108. For example, the metal grid 212 may stand on the first passivation layer 104 and be surrounded by the oxide grid 108. The oxide grid 108 may have a bottom width wider than that of the metal grid 212 such that the metal grid 212 is spaced apart from the color filter array 110 by the oxide grid 108. The metal grid 212 may also have a trapezoid shape with sidewalls having a slope similar to the sidewalls of the oxide grid 108. The metal grid 212 may have a height smaller than that of the oxide grid 108. For example, the metal grid may have a height of between about 0.05 μm and about 1.0 μm. The metal grid 212 has a bottom width of about 5.7% to about 20% of the periodic interval 108P of the oxide grid 108 (or the width of the unit pixels 100A). In an embodiment, the metal grid 212 may be formed of W, Cu, AlCu or a combination thereof.

The oxide grid 108 may have a refractive index smaller than that of all of the color filters 110. In addition, the metal grid 212 may have an extinction coefficient greater than zero for blocking the incident light diffusion. For example, the metal grid 212 may mainly block the incident light by absorbing it, and the oxide grid 108 may mainly block the incident light by reflecting it. In this embodiment, the portion of the incident light that is not reflected by and penetrates into the oxide grid 108 may be absorbed by the metal grid 212. In addition, the BSI CMOS image sensor may have a reduced total thickness since the metal grid 212 is embedded in the oxide grid 108. Thus, the BSI CMOS image sensor may have high quantum efficiency and low cross-talk with a reduced total thickness.

A microlens structure 114 may be disposed on the color filter array 110 and the oxide grid 108 for focusing an incident light toward the photodiode array 102 and reducing the incident light diffusion. An interconnection layer 116 may be formed on the back surface of the semiconductor substrate, independent of the optical path.

FIG. 3 shows a cross-sectional view of a BSI CMOS image sensor according to yet another embodiment of the present disclosure. In this embodiment, the BSI CMOS image sensor is similar to the BSI image sensor shown in FIG. 2 except that the metal grid is interposed between the oxide grid and the color filters. Like reference numerals in this embodiment are used to indicate elements substantially similar to the elements described in the above embodiments, and thus a detailed description of the substantially similar elements will not be repeated.

Referring to FIG. 3, the oxide grid 108 and the metal grid 312 may be disposed in an upper portion and a lower portion, respectively, of holes formed by the color filters 110. The sidewalls of the metal grid 312 may directly contact the color filters 110. In this embodiment, a portion of the incident light that is not reflected by and penetrating into the oxide grid 108 may be absorbed by the metal grid 110. When compared to the BSI CMOS image sensor as shown in FIG. 2, the metal grid 312 may have a larger surface area which may further reduce the cross-talk.

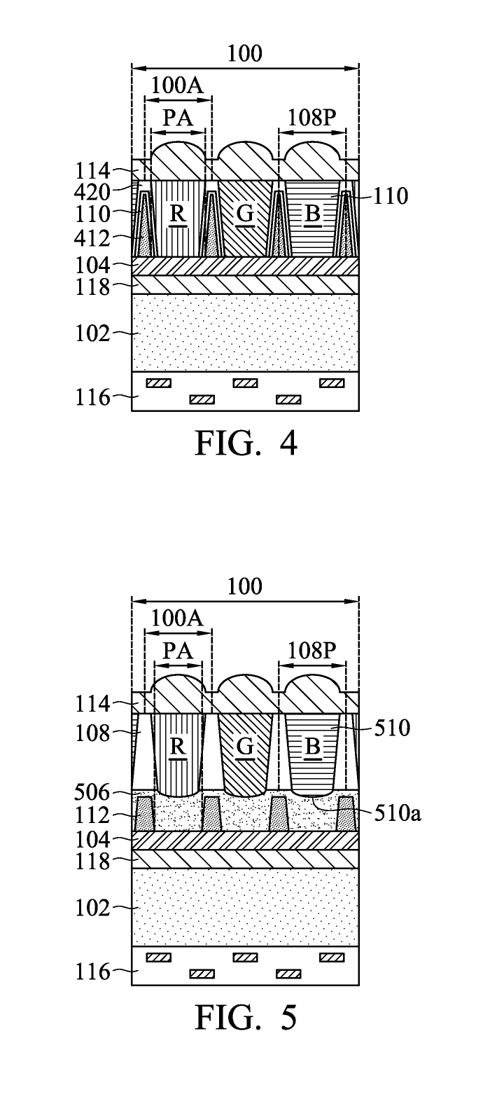

FIG. 4 shows a cross-sectional view of a BSI CMOS image sensor according to another embodiment of the present disclosure. In this embodiment, the BSI CMOS image sensor is similar to the BSI image sensor shown in FIG. 2 except that an additional grid may be interposed between the oxide grid and the color filters. Like reference numerals are used to indicate elements substantially similar to the elements described in the above embodiments, and thus a detailed description of the substantially similar elements will not be repeated.

Referring to FIG. 4, in addition to the metal grid and the oxide grid, an additional grid 420 may be interposed between the oxide grid 108 and the color filters 110. The additional grid 420 may surround the oxide grid 108 and have sidewalls directly contacting the color filters 110. The additional grid 420 may have a refractive index larger than that of the oxide grid 108. For example, the additional grid 420 may be formed of SiN, Ta₂O₅, HfO₂ or a combination thereof. Since the additional grid 420 may have a refractive index greater than that of the oxide grid 108, more portions of the incident light can be reflected by the additional grid 420 and the oxide grid 108, resulting in higher quantum efficiency.

FIG. 5 shows a cross-sectional view of a BSI CMOS image sensor according to an alternative embodiment of the present disclosure. In this embodiment, the BSI CMOS image sensor is similar to the BSI CMOS image sensor shown in FIG. 1 except that the color filters depress into the second passivation layer. Like reference numerals are used to indicate elements substantially similar to the elements described in the above embodiments, and thus a detailed description of the substantially similar elements will not be repeated.

Referring to FIG. 5, the color filters 510 and the second passivation layer 506 may have a concave interface 510A which depresses into the second passivation layer 506. In this embodiment, light beams cross the interface 510a between color filters 510 and the second passivation layer 506 that are formed of different materials and have different refractive indices. In order to achieve excellent color characteristics, the light-passing interface 510a can be concave (depressing into the second passivation layer 506). The shape of the interface is determined by the corresponding refractive indices of the color filters and the second passivation layer. For instance, if the color filter exhibits a larger refractive index than that of the second passivation layer, the interface respectively is concave and depressed into the second passivation layer. In this embodiment, the color filters 510 have a larger refractive index than that of the second passivation layer 506 while the light-passing interface 510a is concave.

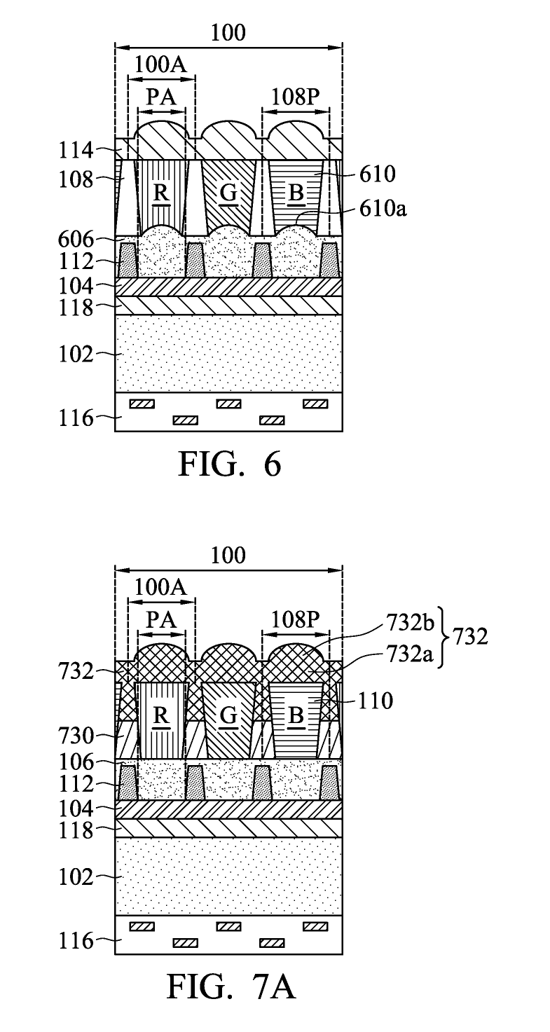

FIG. 6 shows a cross-sectional view of a BSI CMOS image sensor according to another alternative embodiment of the present disclosure. In this embodiment, the BSI CMOS image sensor is similar to the BSI CMOS image sensor shown in FIG. 1 except that an interface between the color filters and the second passivation layer is convex. Like reference numerals are used to indicate elements substantially similar to the elements described in the above embodiments, and thus a detailed description of the substantially similar elements will not be repeated.

Referring to FIG. 6, the color filters 610 and the second passivation layer 606 may have a convex interface 610A which depresses into the color filters 610. In this embodiment, light beams cross the interface 610a between color filters 610 and the second passivation layer 606 that are formed of different materials and have different refractive indices. In order to achieve excellent color characteristics, the light-passing interface 610a can be convex (bulging outwards from the second passivation layer 606). The shape of the interface is determined by the corresponding refractive indices of the color filters and the second passivation layer 606. For instance. For instance, if the color filter exhibits a smaller refractive index than that of the second passivation layer, the interface respectively is convex and bulging outwards from the second passivation layer. In this embodiment, the color filters 610 have a smaller refractive index than that of the second passivation layer 606 while the light-passing interface 610a is convex.

In other embodiments, the color filters and the second passivation layer may have the same refractive index with a flat interface between the color filters and the second passivation layer, as shown in FIGS. 1A-4.

In some embodiments, to enhance the quantum efficiency and incident light flux of the photodiodes, the refractive index of the passivation layers and the microlens array may also be varied.

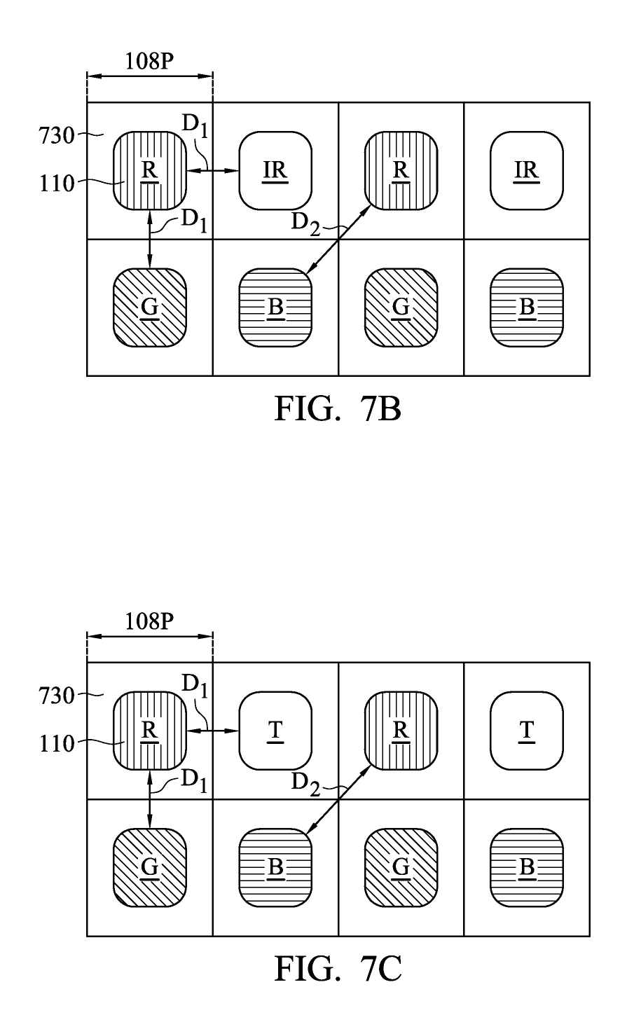

FIG. 7A shows a cross-sectional view of a BSI CMOS image sensor according to some embodiments of the present disclosure. The BSI CMOS image sensor may comprise a pixel region 100 in which a plurality of unit pixels 100A is arranged in a semiconductor substrate made of silicon, and a peripheral circuit section (not shown) disposed in a periphery of the pixel region 100. A photodiode array 102 comprising a plurality of photodiodes and a plurality of pixel transistors (not shown) may be formed through the overall region of the semiconductor substrate in the pixel region 100.

A first passivation layer 104 and a second passivation layer 106 may be disposed on the photodiode array 102. In some embodiments, an interconnection layer 116 may be formed on the back surface of the photodiode array, independent of the optical path. In an embodiment, the second passivation layer 106 may be disposed on the first passivation layer 104. The first passivation layer 104 and the second passivation layer 106 may be formed of the same or different materials. For example, the first and second passivation layers 104 and 106 may be formed of silicon oxide, silicon nitride, aluminum oxide, Ta₂O₅, HfO₂, or a combination thereof. The first and second passivation layers 104 and 106 may function as an etch stop layer during the fabrication of the peripheral circuit (not shown). In some embodiments, the first passivation layer 104 can be omitted if it is permitted by the fabricating process. Alternatively, another passivation layer 118 or more passivation layers may be formed between the passivation layers 104 and 106 and the photodiode array 102.

A color filter array 110 comprising a plurality of color filters 110 is formed on the second passivation layer 106. Each of the color filters 110 corresponds to one of the photodiodes (not shown) of the photodiode array 102. The color filters 110 may be formed as a grid and have spaces therebetween. In an embodiment, the color filters 110 may have substantially vertical sidewalls (e.g., about 85° to about 100°). In another embodiment, the color filters may have reverse-tapered sidewalls, and each of the color filters 110 may have a bottom surface narrower than or equal to its top surface.

The color filters 110 may at least comprise three primary colors, such as red, green, and blue (R, G and B), arranged in any suitable combination. For example, the color filters 110 may arranged according to arrangement shown in FIG. 1B. In addition, the color filters 110 may further comprise a transparent (T) filter and/or an infrared (IR) filter. For example, FIG. 7B shows a top view of the BSI CMOS image sensor according to an embodiment of the present disclosure while removing second grid 732. In FIG. 7B, the three primary colors, such as RGB, and a transparent (T) filter are alternatively arranged. Alternatively, FIG. 7C shows a top view of the BSI CMOS image sensor according to another embodiment of the present disclosure while removing second grid 732. In FIG. 7C, the three primary colors, such as RGB, and an IR or transparent (T) filter are alternatively arranged.

A first grid 730 is filled into the spaces between the color filters 110 and stands on the second passivation layer 106. From the top view, (e.g., referring to FIGS. 7B and 7C) the first grid 730 is made up of a series of intersecting perpendicular and horizontal axes for separating the adjacent color filters 110. The first grid 730 may have a periodic interval 108P substantially equal to the width of the unit pixels 100A. The color filters 110 are divided by the first grid 730. In an embodiment, a distance from a color filter 110 to its nearest color filter 110 may be a width D₁ ranging from about 7% to about 30% of the periodic interval 108P. In some embodiments, a distance from a color filter 110 to its second nearest color filter 110 may be a width D₂ ranging from about 20% to about 70% of the periodic interval 108P.

The first grid 730 surrounds a lower portion of the sidewalls of the color filters 110. In some embodiments, the first grid 730 has a height lower than that of the color filters 110. The first grid 730 may have a rectangular shape in the cross-sectional view, as shown in FIG. 7A. However, it is understood that the first grid 730 may have other suitable shapes, such as a trapezoidal shape. In some embodiments, the height of the first grid 730 and the height of the color filter 110 may have a ratio of between about 20% to about 80%. In a specified example, the height of the first grid 730 may be half that of the color filters 110. In some embodiments, the first grid 730 has a refractive index that is lower than about 1.46 and that of all the color filters 110 (including R, G and B). In some embodiments, the first grid may have a refractive index that is lower than about 1.2. For example, the first grid 730 may comprise a polymer material doped with a dopant which is used for tuning (e.g., reducing) the refractive index. The polymer material may include polyamide, polyimide, polystyrene, polyethylene, polyethylene terephthalate, polyurethane, polycarbonate, polymethyl methacrylate (PMMA) or combinations thereof. The dopant may be pigments or dyes. The dopant may have an average diameter ranging from about 20 nm to 200 nm. For example, the pigments or dye may include a black color. In some embodiments, the pigments or dye include carbon black, titanium black or combinations thereof.

The second grid 732 is filled into the remaining spaces between the color filters 110 and stands on the first grid 730. In some embodiments, the second grid 732 may have a first portion 732a surrounding an upper portion of the sidewalls of the color filters 110 and a second portion 732b extending from the top of the first portion 732a of the second grid 732. The top of the first portion 732a may be higher than or level with the top surface of the color filters 110. The second portion 732b of the second grid 732 may have a plurality of microlens units aligned with the color filters 110. The microlens units may form a microlens array of the BSI CMOS image sensor. The microlens array of the BSI CMOS image sensor is integrated with the spacers, such as the first portion 732a of the second grid 732, between the color filter 110. The microlens array of the BSI CMOS image sensor is used to focus incident light to the photodiode array 102 while reducing the incident light diffusion.

In some embodiments, the second grid 732 may have a refractive index that is higher than that of the first grid 730 but lower than that of all the color filters 110. In other embodiments, the second grid 732 has a refractive index that is substantially equal to or lower than the refractive index of the first grid 730, according to the desired optical path directed to the photodiodes. For example, the second grid 732 may be formed of a polymer material doped with a dopant which is used for tuning (e.g., reducing) the refractive index to the desired value. The polymer material may include polyamide, polyimide, polystyrene, polyethylene, polyethylene terephthalate, polyurethane, polycarbonate, polymethyl methacrylate (PMMA) or combinations thereof. The dopant may be pigments or dyes. The dopant may have an average diameter ranging from about 20 nm to 200 nm. For example, the pigments or dye may include a black color. In some embodiments, the pigments or dye include carbon black, titanium black or combinations thereof.

A metal grid 112 may be embedded in the second passivation layer 106. For example, the metal grid 112 may stand on the first passivation layer 104 and align with the first grid 730. In addition, the metal grid 112 may be spaced apart from the first grid 730 and the color filters 110 by the second passivation layer 106 such that the oxide grid 108 may be protected by the second passivation layer 116. The metal grid 112 may be arranged periodically around the unit pixels 100A to prevent damage from static electricity. The metal grid 112 may have tapered sidewalls (i.e., having a trapezoidal shape in the cross-sectional view).

The metal grid 112 may have an extinction coefficient that is greater than zero for blocking the incident light diffusion. For example, the metal grid 112 may mainly block the incident light by absorbing it, and the grids 730 and 732 may mainly block the incident light by reflecting it.

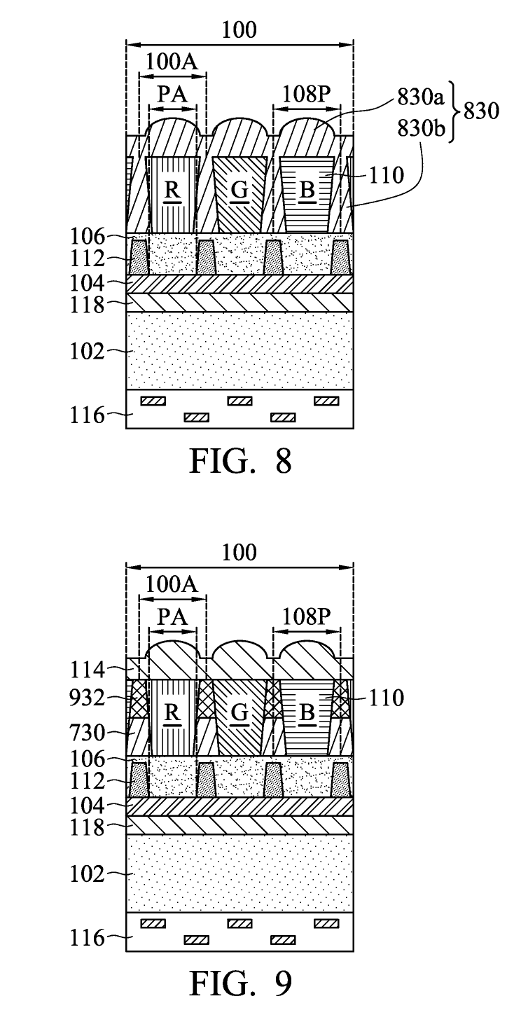

FIG. 8 shows a cross-sectional view of a BSI CMOS image sensor according to some embodiments of the present disclosure. In this embodiment, the BSI CMOS image sensor is similar to the BSI CMOS image sensor shown in FIG. 7 except that there is no need for the formation of the second grid. Like reference numerals in this embodiment are used to indicate elements substantially similar to the elements described in the above embodiments, and a detailed description of the substantially similar elements will not be repeated.

Referring to FIG. 8, a grid 830 is filled into the spaces between the color filters 110 and stands on the second passivation layer 106. The grid 830 has a first portion 830a surrounding the entirety of the sidewalls of the color filters 110 and a second portion 830b extending from the top of the first portion 830a of the grid 830. The first portion 830a of the grid 830 may have a trapezoidal shape in the cross-sectional view and have a periodic interval 108P substantially equal to the width of the unit pixels 100A. In some embodiments, the top of the first portion 830a may be higher than or level with the top surface of the color filters 110.

The second portion 830b of the grid 830 may have a plurality of microlens units aligned with the color filters 110. The microlens units may form a microlens array of the BSI CMOS image sensor. The second portion 830b of the first grid 730 may have a height of about 50% to about 80% of the periodic interval 108P. The microlens array of the BSI CMOS image sensor is integrated with the spacers, such as the first portion 830a of the grid 830, between the color filters 110. In some embodiments, the grid 830 has a refractive index that is lower than about 1.46 and that of all the color filters 110 (including R, G and B). In some embodiments, the grid 830 may have a refractive index that is lower than about 1.2. In some embodiments, the grid 830 may include the same material as the first grid 730 as described above in the preceding embodiments.

FIG. 9 shows a cross-sectional view of a BSI CMOS image sensor according to some embodiments of the present disclosure. In this embodiment, the BSI CMOS image sensor is similar to the BSI CMOS image sensor shown in FIG. 7, except that an additional microlens structure 114 is formed on the color filters 110. Like reference numerals in this embodiment are used to indicate elements substantially similar to the elements described in the above embodiments, and a detailed description of the substantially similar elements will not be repeated.

Referring to FIG. 9, the first grid 730 and a second grid 932 are filled into the spaces between the color filters 110. The first grid 730 stands on the second passivation layer 106 and surrounds a lower portion of the sidewalls of the color filters 110. The second grid 932 stands on the first grid 730 and surrounds an upper portion of the sidewalls of the color filters 110. In some embodiments, the total height of the first grid 730 and the second grid 932 is substantially equal to the height of the color filters 110.

In some embodiments, the second grid 932 may have a refractive index that is higher than that of the first grid 730 but lower than that of the color filters 110. In other embodiments, the second grid 932 has a refractive index that is substantially equal to or lower than the refractive index of the first grid 730, according to the desired optical path directed to the photodiodes. For example, the second grid 932 may include the same material as the second grid 732 as described above in the preceding embodiments.

A microlens structure 114 is formed on the color filters 110 and the second grid 932. The refractive index of the microlens structure 114 may be suitably varied according to the optical requirements of the BSI CMOS image sensor. The microlens structure 114 may have a refractive index either higher or lower than 1.47. The microlens structure 114 may have a height of about 50% to about 80% of the periodic interval 108P.

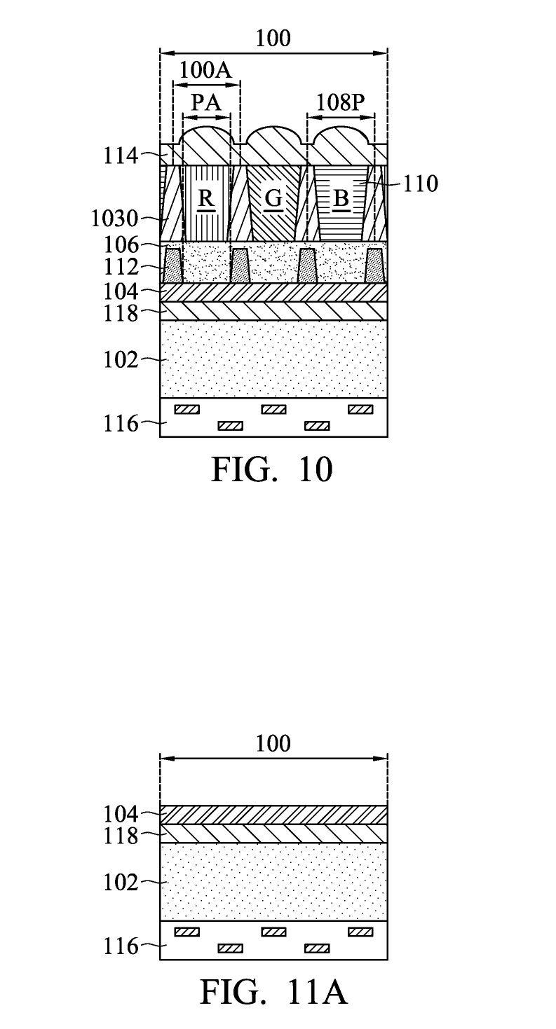

FIG. 10 shows a cross-sectional view of a BSI CMOS image sensor according to some embodiments of the present disclosure. In this embodiment, the BSI CMOS image sensor is similar to the BSI CMOS image sensor shown in FIG. 8, except that an additional microlens structure 114 is formed on the color filters 110. Like reference numerals in this embodiment are used to indicate elements substantially similar to the elements described in the above embodiments, and a detailed description of the substantially similar elements will not be repeated.

Referring to FIG. 10, a grid 1030 is filled into the spaces between the color filters 110. The grid 1030 stands on the second passivation layer 106 and surrounds the entirety of the sidewalls of the color filters 110. In some embodiments, the height of the grid 1030 is substantially equal to the height of the color filters 110.

In some embodiments, the grid 1030 may have a lower refractive index than that of the color filters 110. For example, the grid 1030 may have a refractive index that is lower than about 1.46. In some embodiments, the grid 1030 may have a refractive index that is lower than about 1.2. For example, the grid 1030 may include the same material as the first grid 730 as described above in the preceding embodiments.

A microlens structure 114 is formed on the color filters 110 and the second grid 932. The refractive index of the microlens structure 114 may be suitably varied according to the optical requirements of the BSI CMOS image sensor. The microlens structure 114 may have a refractive index either higher or lower than 1.47. In an embodiment, the microlens structure 114 may comprise organic material, inorganic compound or intermetallic compound. The microlens structure 114 may have a height of about 50% to about 80% of the periodic interval 108P.

When compared to the conventional BSI CMOS image sensor, the spacers between the color filters of the BSI CMOS image sensor according to the present disclosure are formed of a grid with an ultra-low refractive index. Therefore, the fraction of total reflection of the incident light may be increased. Photo-crosstalk between adjacent pixel units may be reduced, and the intensity of the incident light directed to the photodiodes may be enhanced. The performance of the BSI CMOS image sensor may be improved with enhanced quantum efficiency.

In addition, in some embodiments of the present disclosure, since the microlens array and the spacers of the BSI CMOS image sensor have the same refractive index and are integrated with each other, one or more refractions can be obviated, and the process of adhering an additional microlens array to the color filters may be omitted. The BSI CMOS image sensor is therefore simply fabricated and cost-effective while having large incident light flux.

In some embodiments, a microlens structure having a relatively higher refractive index has a relatively lower height when compared to a microlens structure having a relatively lower refractive index. It is easier to fabricate the microlens structure of the relatively higher refractive index by using the microlens structure having the relative refractive index. In addition, the sensitivity may be enhanced due to the total height of the BSI CMOS image sensor is relatively lower. In other embodiments, by using the microlens structure having a relatively lower refractive index, one or more refractions can be obviated can be obviated because the refraction indexes of the microlens structure and the spacers are increased along the travelling direction of the incident light.

In addition to the embodiments described above, the BSI CMOS structure according to the present disclosure may be varied within the scope of the present disclosure. For example, the BSI CMOS structure shown in FIGS. 7-10 may also comprise a concave or convex interface between the grid and the second passivation layer.

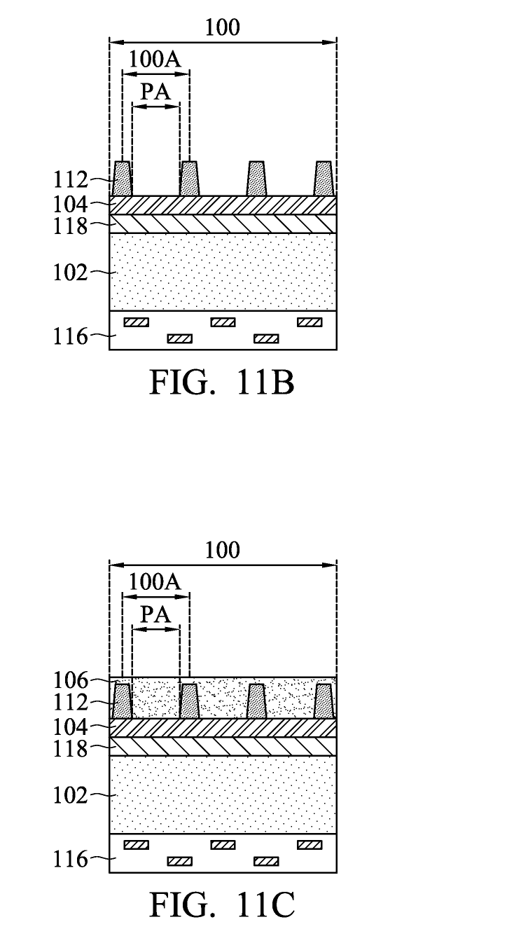

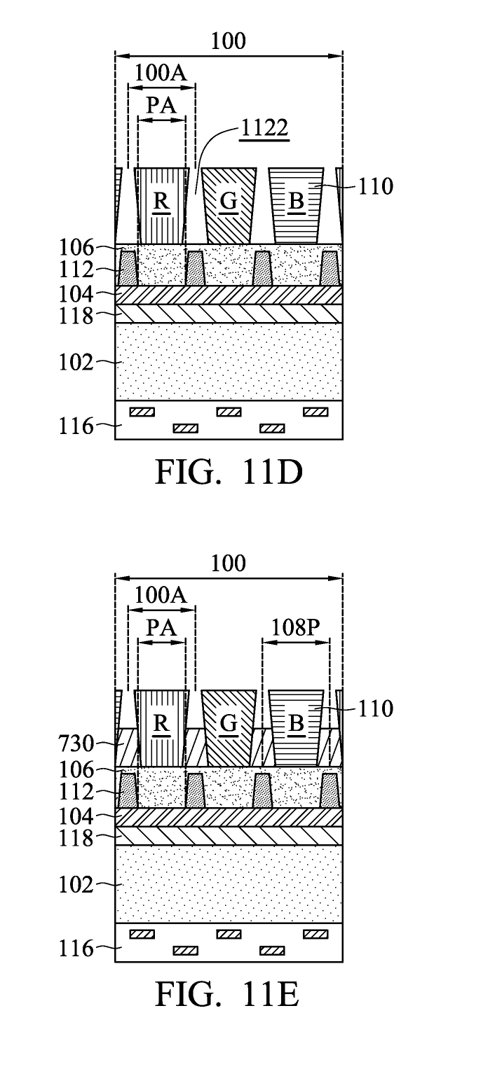

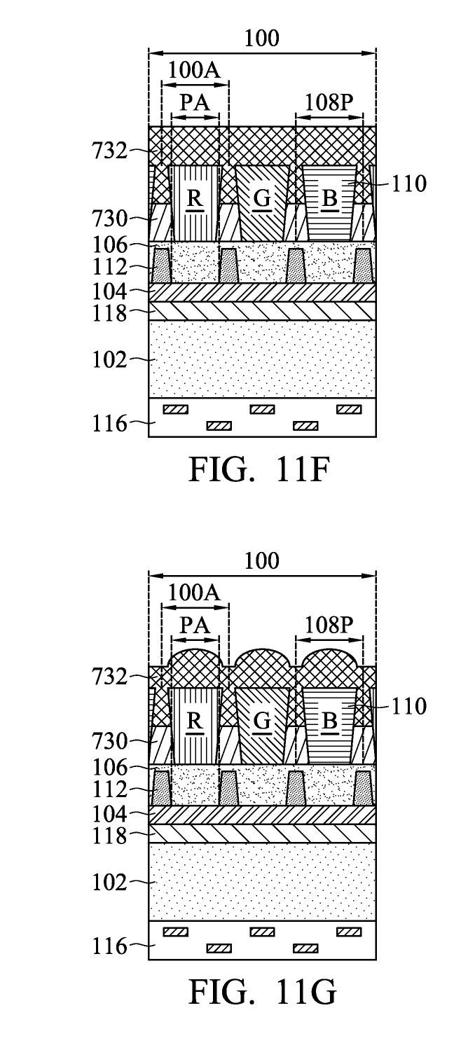

FIGS. 11A to 11G show cross-sectional views at intermediate stages of forming the BSI CMOS image sensor shown in FIG. 7. Referring to FIG. 11A, the photodiode array 102 is provided with the interconnection structure 106. The third passivation layers 118 and 104 are formed on the photodiode array 102.

Referring to FIG. 11B, the metal grid 112 is formed on the first passivation layer 104. The metal grid 112 may be formed by: forming a metal layer on the first passivation layer 104 by sputtering or electroplating, and then the metal layer is patterned into a grid by suitable etching processes. Referring to FIG. 11C, after forming the metal grid 112, the passivation layer 106 is deposited to fill the spaces between the metal grid 112. The passivation layer 106 has a thickness greater than the cover of the metal grid 112 to cover it.

Afterwards, referring to FIG. 11D, the color filter array 110 comprising a plurality of color filters 110 is formed on the passivation layer 106. Each of the color filters 110 may correspond to the photodiodes of the photodiode array 102 and have spaces 1122 therebetween.

Referring to FIG. 11E, the first grid 730 is then filled into the spaces 1122 between color filters 110. As described above, the first grid 730 may have a height that is lower than that of the color filters 110. In some embodiments, the first grid 730 may be formed by spin coating process and lithograph. Afterwards, referring to FIG. 11F, the second grid 732 is formed on the first grid 730 and fills the remaining spaces 1122 between the color filters 110. The second grid 732 may be formed by the same method as the first grid 730. As shown in FIG. 11F, the top of the second grid 732 may be higher than the top surface of the color filters 110, such as higher than a value of from about 0.3 to about 0.7.

Afterwards, referring to FIG. 11G, the second grid 732 is patterned to comprise a plurality of microlens units. Each of the microlens units of the second grid corresponds to one of the underlying color filters 110.

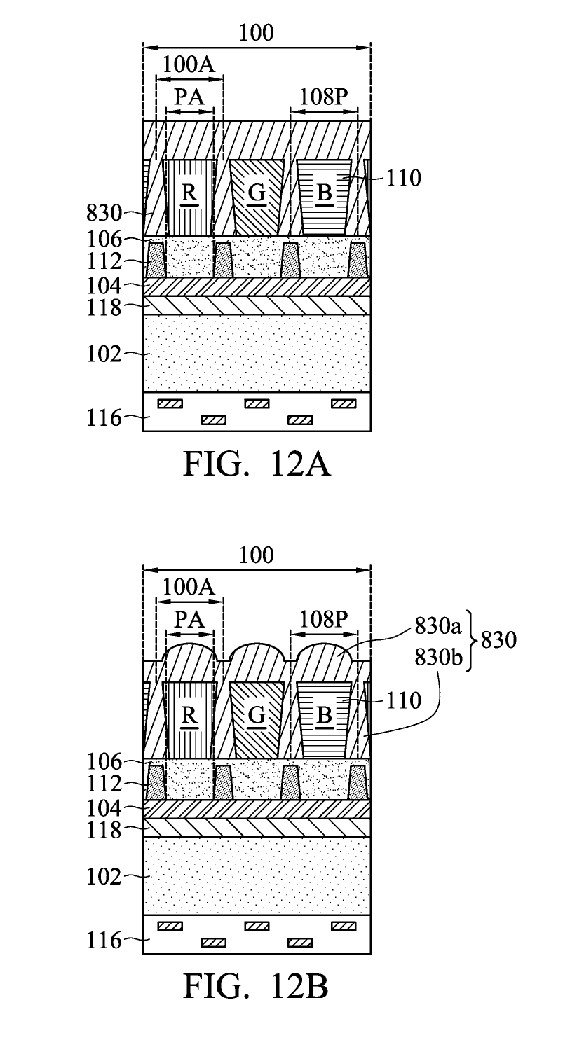

FIGS. 12A to 12B show cross-sectional views at intermediate stages of forming the BSI CMOS image sensor shown in FIG. 8. Referring to FIG. 12, the steps shown in FIGS. 11A to 11D are repeated, and the grid 830 is then filled into the spaces between the color filters 110 and stands on the passivation layer 106. The grid 830 may be formed by a spin coating process and then performing lithography process. In some embodiments, the top of the grid 830 is higher than the top surface of the color filters 110. For example, the distance between the top of the grid 830 and the top surface of the color filters may be between about 0.3 μm and about 0.7 μm, depending on the needs of the optical designs.

Afterwards, referring to FIG. 12B, the grid 830 is patterned to comprise a plurality of microlens units 830b. Each of the microlens units 830b of the grid 830 corresponds to one of the underlying color filters 110.

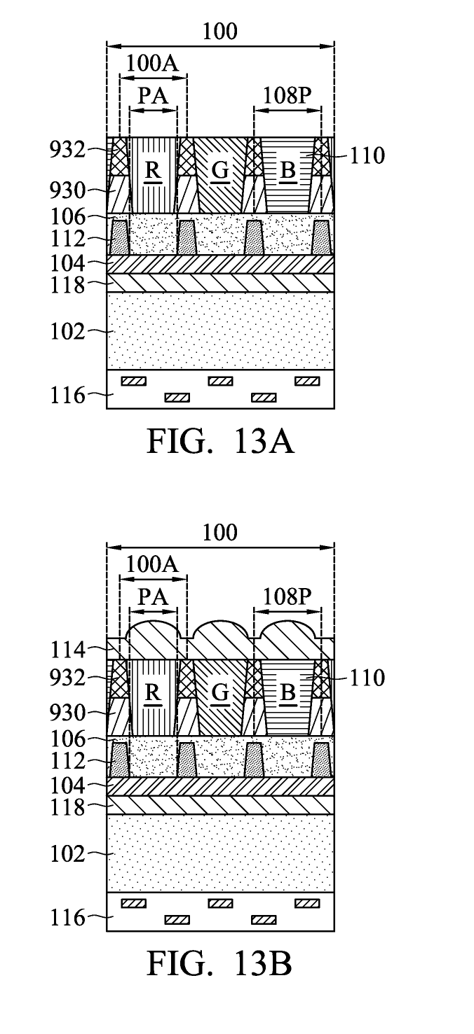

FIGS. 13A to 13B show cross-sectional views at intermediate stages of forming the BSI CMOS image sensor shown in FIG. 9. Referring to FIG. 12, the steps shown in FIGS. 11A to 11E are repeated, and the grid 932 is then filled into the spaces 1122 between the color filters 110 and stands on the passivation layer 106. In this stage, the second grid 932 may have a top higher than the top surface of the color filters 110. Thereafter, a planarization process, such as chemical metal polishing, may be performed to the second grid 932 so that the top of the second grid 932 is substantially level with the top of the color filters 110.

Afterwards, referring to FIG. 13B, an additional microlens structure 114 is adhered onto the color filters 110 and the second grid 932.

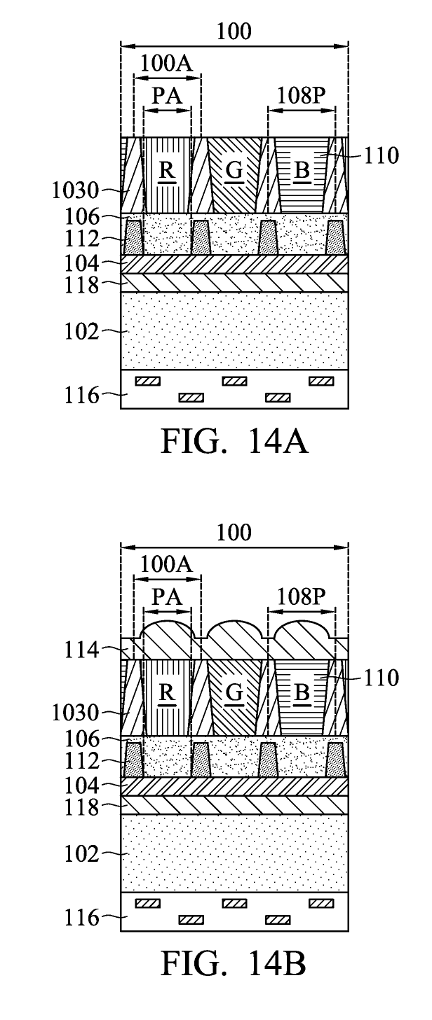

FIGS. 14A to 14B show cross-sectional views at intermediate stages of forming the BSI CMOS image sensor shown in FIG. 10. Referring to FIG. 14A, the steps shown in FIGS. 11A to 11E are repeated, and the grid 1030 is then filled into the spaces between the color filters 110 and stands on the passivation layer 106. As shown in FIG. 14A, the top of the grid 1030 is higher than the top of the color filters 110.

Afterwards, referring to FIG. 14B, the grid 1030 is polished to have a top surface level with the top surface of the color filters 110. The grid 1030 may be polished by any suitable polishing method. An additional microlens structure 114 is then adhered onto the color filters 110 and the grid 1030.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A back-surface illuminated CMOS image sensor, comprising
a substrate comprising a photodiode array;
a passivation layer disposed on the photodiode array;
a color filter array comprising a plurality of color filters formed on the passivation layer, wherein each of the color filters corresponds one photodiode of the photodiode array;
a first grid formed on the passivation layer and filled into the spaces between the plurality of color filters, wherein the first grid has a refractive index of lower than about 1.46 and that of the plurality of color filters; and
a metal grid aligned to the first grid between the plurality of color filters, wherein the metal grid has an extinction coefficient that is greater than zero.

2. The back-illuminated image sensor as claimed in claim 1, wherein the first grid comprises a first portion surrounding the sidewalls of the color filter array and a second portion extending from the top of the first portion of the first grid and comprising a plurality of microlens units aligned with the color filter array.

3. The back-illuminated image sensor as claimed in claim 1, wherein the first grid has substantially the same height as that of the color filter array.

4. The back-illuminated image sensor as claimed in claim 3, further comprising a microlens array over the first grid and the color filter array, wherein the microlens array has a refractive index that is between about 1.5 and about 1.9.

5. The back-illuminated image sensor as claimed in claim 1, further comprising a second grid on the first grid.

6. The back-illuminated image sensor as claimed in claim 5, wherein the second grid comprises a first portion surrounding a portion of the sidewalls of the color filter array and a second portion extending from the top of the first portion of the second grid and comprising a plurality of microlens units aligned to the plurality of color filters.

7. The back-illuminated image sensor as claimed in claim 5, further comprising a microlens array on the second grid and color filter array, wherein the microlens array has a refractive index that is between about 1.5 and about 1.9.

8. The back-illuminated image sensor as claimed in claim 5, further comprising a microlens array on the second grid and color filter array, wherein the microlens array has a refractive index that is lower than 1.46.

9. The back-illuminated image sensor as claimed in claim 8, wherein the first grid surrounds a lower portion of the sidewalls of the color filter array, and the second grid surrounds an upper portion of the sidewalls of the color filter array.

10. The back-illuminated image sensor as claimed in claim 5, wherein the second grid has a lower refractive index than that of the first grid.

11. The back-illuminated image sensor as claimed in claim 5, wherein the second grid has a refractive index that is greater than that of the first grid and lower than 1.46 and that of the plurality of color filters.

12. The back-illuminated image sensor as claimed in claim 5, wherein the first and second grids comprise a polymer material doped with a pigment or a dye.

13. A method for forming a back-illuminated image sensor, comprising:
providing substrate comprising a photodiode array;
forming a metal layer on the photodiode array;
patterning the metal layer to form a metal grid, wherein the metal grid has an extinction coefficient that is greater than zero;
forming a passivation layer covering the metal grid;
forming a color filter array comprising a plurality of color filters on the passivation layer, wherein the plurality of color filters forms a plurality of holes exposing the passivation layer and aligning to the interval of space between the metal grid; and
filling a first grid into the holes, wherein the first grid has a refractive index that is lower than about 1.46 and that of the color filters.

14. The method as claimed in claim 13, wherein the first grid has an overfilled portion above the plurality of holes, and the overfilled portion of the first grid is then patterned to comprise a plurality of microlens units aligned with the plurality of color filters.

15. The method as claimed in claim 13, further comprising forming a microlens array on the first grid and the plurality of color filters.

16. The method as claimed in claim 15, further comprising performing a planarization process to the first grid before forming the microlens array.

17. The method as claimed in claim 13, further comprising filling a second grid into the holes after filling the first grid.

18. The method as claimed in claim 17, wherein the second grid has an overfilled portion above the plurality of holes, and the overfilled portion of the second grid is then patterned to comprise a plurality of microlens units aligned to the plurality of color filters.

19. The method as claimed in claim 17, further comprising forming a microlens array on the second grid.

20. The method as claimed in claim 19, further comprising performing a planarization process to the second grid before forming the microlens array.
